(19) United States
(12) Patent Application Publication
(10) Pub. No.: US 2022/0190277 A1
(43) Pub. Date: Jun. 16, 2022

(54) FLEXIBLE COVER PLATE, FLEXIBLE DISPLAY DEVICE, AND MANUFACTURING METHOD OF FLEXIBLE COVER PLATE

(71) Applicant: Wuhan China Star Optoelectronics Semiconductor Display Technology Co., Ltd., Wuhan, Hubei (CN)

(72) Inventor: Xia CHEN, Wuhan (CN)

(21) Appl. No.: 16/651,240

(22) PCT Filed: Feb. 18, 2020
(86) PCT No.: PCT/CN2020/075640

§ 371 Date: Mar. 26, 2020

(30) Foreign Application Priority Data
Aug. 22, 2019 (CN) 201910778033.1

(51) Int. Cl. H01L 51/52; H01L 51/00; H01L 51/56

(52) U.S. Cl. CPC H01L 51/524; H01L 2251/5338; H01L 51/56; H01L 51/0097

(57) ABSTRACT

A flexible cover plate, a flexible display device, and a manufacturing method of a flexible cover plate are provided. The flexible cover plate is used as a protective cover of a flexible display device, and the flexible cover plate includes a flexible substrate, a hardened layer, and an ink protective layer. The hardened layer is disposed on a side of the flexible substrate. The ink protective layer is disposed at edges around the hardened layer and the flexible substrate, which are laminated. The flexible cover plate can prevent the hardened layer from cracking from the edge after bending with the flexible substrate several times.

### FIELD OF DISCLOSURE

The present application relates to the field of display technology, and particularly relates to a flexible cover plate, a flexible display device, and a manufacturing method of a flexible cover plate.

### BACKGROUND OF DISCLOSURE

With the development of high-performance electronic products, flexible and bendable consumer electronic products have attracted investment and development of major manufacturers. To achieve dynamic bending display products, new materials, new designs, and new manufacturing processes must be introduced to improve the performance of the flexible and bendable display products.

### SUMMARY OF DISCLOSURE

### Technical Problems

The biggest challenge of the flexible and bendable display products is a flexible cover plate. Instead of surface glass in a hard screen, the flexible cover plate is attached to the outermost surface of the display, which needs good bending resistance, scratch resistance, and high surface hardness. Generally, a transparent flexible material is used as a base material, and then a front surface thereof is coated with a hardened layer to improve the surface hardness. However, the hardened layer is mostly made by a brittle material of a layer of silicon-containing inorganic material combined with an organic material. In the flexible display products, if the bending times are too many or the bending radius is too small, the hardened layer is easily cracked from the edge, and the crack extension may lead to bending failure.

### Technical Solutions

The present application provides a flexible cover plate, a flexible display device, and a manufacturing method of a flexible cover plate to solve the problem that the hardened layer is easily cracked in the prior art.

To solve the above technical problems, one technical solution of the present application is to provide a flexible cover plate. The flexible cover plate is used as a protective cover of a flexible display device. The flexible cover plate comprises a flexible substrate, a hardened layer, and an ink protective layer. The hardened layer is disposed on a side of the flexible substrate. The ink protective layer is disposed at edges around the hardened layer and the flexible substrate, which are laminated.

To solve the above technical problems, another technical solution of the present application is to provide a flexible display device. The flexible display device comprises an organic light-emitting panel and the flexible cover plate disposed in a stack.

To solve the above technical problems, another technical solution of the present application is to provide a manufacturing method of a flexible cover plate. The manufacturing method comprises steps as follows. A hardened material is coated on an original flexible substrate material plate to form a hardened layer. An ink is coated at edges of the hardened layer and the flexible substrate, which are laminated, to form a semi-enclosed ink layer.

### Beneficial Effects

The beneficial effects of the present application are as follows. The flexible cover plate comprises a flexible substrate, a hardened layer, and an ink protective layer. The hardened layer is disposed on a side of the flexible substrate. The ink protective layer is disposed at edges around the hardened layer and the flexible substrate, which are laminated. The hardened layer is used to improve the surface hardness of the flexible substrate. The ink protective layer is disposed at edges around the hardened layer and the flexible substrate, which are laminated, thereby preventing the hardened layer from cracking from the edge after bending with the flexible substrate several times.

### DESCRIPTION OF DRAWINGS

In order to clearly illustrate the technical solutions in the embodiments or the prior art, the following briefly introduces the accompanying drawings used in the embodiments or the prior art. Obviously, the drawings in the following description merely show some of the embodiments of the present disclosure. As regards one of ordinary skill in the art, other drawings may be obtained in accordance with these accompanying drawings without making creative efforts.

FIG. 1 is a schematic cross-sectional diagram of a flexible cover plate according to an embodiment of the present application.

FIG. 2 is a schematic diagram of the crack of the flexible cover plate according to the present application.

FIG. 3 is a schematic cross-sectional diagram of the flexible cover plate according to another embodiment of the present application.

FIG. 4 is a schematic cross-sectional diagram of a flexible display device according to an embodiment of the present application.

FIG. 5 is a schematic flowchart of a manufacturing method of a flexible cover plate according to an embodiment of the present application.

FIG. 6 is a schematic flowchart of a manufacturing method of a flexible cover plate according to an embodiment of the present application.

### DETAILED DESCRIPTION OF PREFERRED EMBODIMENTS

The technical solutions in the embodiments of the present application is clearly and completely described in the following. It is obvious that the described embodiments are only a part of the embodiments of the present application, and not all of the embodiments. Based on the embodiments of the present application, all other embodiments obtained by those skilled in the art without creative effort are within the scope of protection of the present application.

Reference herein to “implementation” means that specific features, structures, or characteristic described in connection with the implementations may be included in at least one implementation of the application. The appearances of the phrase in various places in the specification are not necessarily all referring to the same implementation, nor are separate or alternative implementations mutually exclusive of other implementations. As one of ordinary skill in the art explicitly and implicitly appreciate, the implementations described herein may be combined with other implementations.

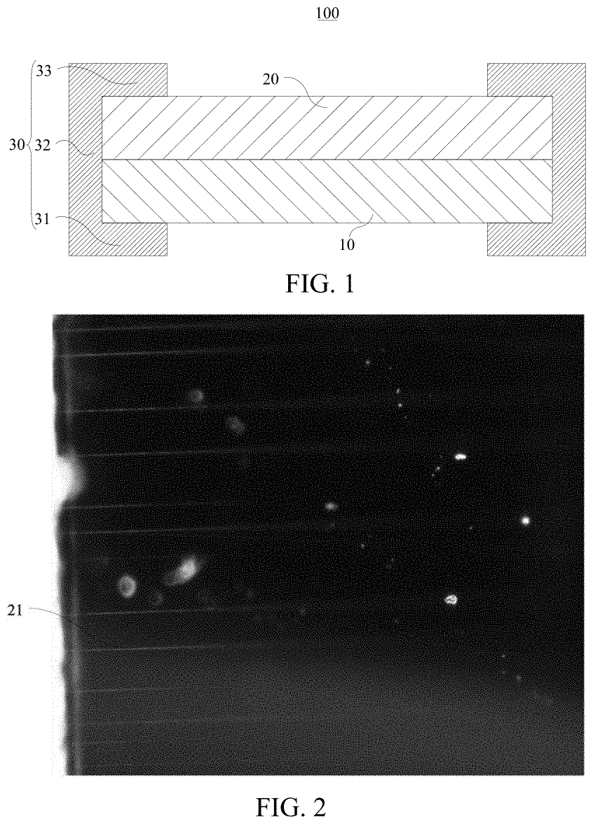

Referring to FIG. 1, FIG. 1 is a schematic cross-sectional diagram of a flexible cover plate 100 according to an embodiment of the present application.

The present application first provides the flexible cover plate 100. The flexible cover plate 100 is used as a protective cover of a flexible display device 1000. The main feature of the flexible display device 1000 is that it can be folded and bent.

In the present embodiment, the flexible cover plate 100 comprises a flexible substrate 10, a hardened layer 20, and an ink protective layer 30. The hardened layer 20 is disposed on a side of the flexible substrate 10, and the ink protective layer 30 is disposed at edges around the hardened layer 20 and the flexible substrate 10, which are laminated.

A material of the flexible substrate 10 may be polyethylene terephthalate or polyimide, so that the flexible substrate 10 has flexibility and light transmittance. The hardened layer 20 is used to improve the surface hardness of the flexible substrate 10. The ink protective layer 30 is disposed at the edges around the hardened layer 20 and the flexible substrate 10, which are laminated, thereby preventing the hardened layer 20 from cracking from the edge after bending with the flexible substrate 10 several times (cracks 21 as shown in FIG. 2). It can be understood that an area of the flexible substrate 10 not covered with the ink protective layer 30 is a light transmitting area.

Particularly, the ink protective layer 30 comprises a first protective layer 31, a second protective layer 32, and a third protective layer 33. The first protective layer 31 is disposed on a side of the flexible substrate 10 away from the hardened layer 20. The third protective layer 33 is disposed on a side of the hardened layer 20 away from the flexible substrate 10. The second protective layer 32 is attached to lateral edges of the hardened layer 20 and the flexible substrate 10, which are laminated, and is respectively connected to the first protective layer 31 and the third protective layer 33.

A thickness of the ink protective layer 30 may ranges from 2 microns to 10 microns, such as 2 microns, 3 microns, 5 microns, 8 microns, or 10 microns.

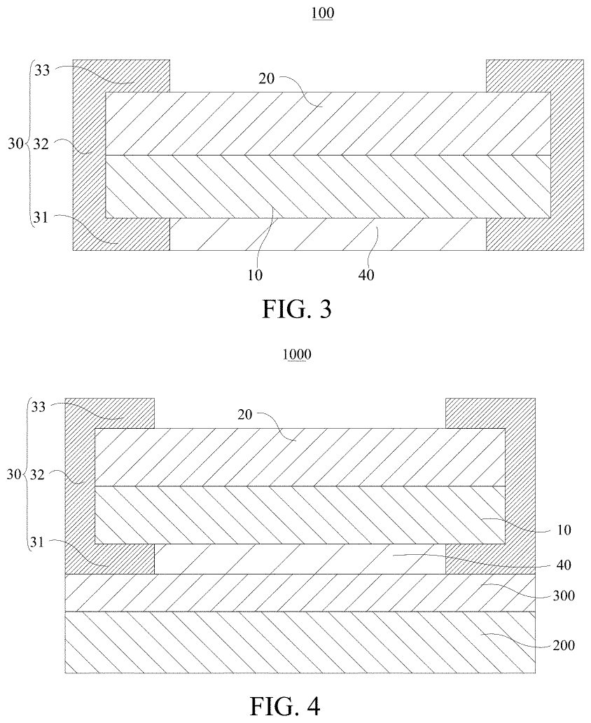

Referring to FIG. 3, FIG. 3 is a schematic cross-sectional diagram of the flexible cover plate 100 according to another embodiment of the present application.

The flexible cover plate 100 further comprises a flexible isolation layer 40. The flexible isolation layer 40 is disposed on a side of the flexible substrate 10 away from the hardened layer 20, and is connected to the first protective layer 31. The flexible isolation layer 40 and the first protective layer 31 are attached to an organic light-emitting panel 200 of the flexible display device 1000 (as shown in FIG. 4). Thus, the introduction of the flexible isolation layer 40 can ensure the flatness of the side of the flexible cover plate 100 provided with the first protective layer 31.

A material of the flexible isolation layer 40 may be polyethylene terephthalate or polyimide, so that the flexible isolation layer 40 has flexibility and light transmittance.

Particularly, the first protective layer 31 comprises a first ink area and a second ink area disposed at intervals. The flexible isolation layer 40 is filled between the first ink area and the second ink area.

The thicknesses of the first ink area and the second ink area are the same, and a surface of the flexible isolation layer 40 away from the flexible substrate 10 is flush with a surface of the first protective layer 31 away from the flexible substrate 10.

Referring to FIG. 4, FIG. 4 is a schematic cross-sectional diagram of the flexible display device 1000 according to an embodiment of the present application.

The present application further provides the flexible display device 1000. The flexible display device 1000 comprises the organic light-emitting panel 200 and the flexible cover plate 100. The flexible cover plate 100 may be the flexible cover plate 100 of any of the above embodiments, and the specific technical features thereof are not described herein again. The side of the flexible cover plate 100 away from the hardened layer 20 faces the organic light-emitting panel 200, and the light emitted from the organic light-emitting panel is emitted from the flexible cover plate 100.

The flexible display device 1000 further comprises an optical adhesive layer 300 disposed between the flexible cover plate 100 and the organic light-emitting panel 200, and the optical adhesive layer 300 is used for bonding the two together.

Particularly, the organic light-emitting panel 200 comprises a base substrate, and an OLED layer, an encapsulation layer, and a polarizing plate sequentially disposed on the base substrate, wherein the side of the organic light-emitting panel 200 provided with the polarizing plate faces the flexible cover plate 100.

The flexible isolation layer 40 of the flexible display device 1000 of the present application can eliminate the step difference caused by the first protective layer 31, so that the optical adhesive layer 300 with a thinner and uniform thickness can be used to bond the light-emitting panel and the flexible cover plate 100, thereby reducing the thickness of the flexible display device 1000, and improving the bending resistance thereof. Moreover, the bonding difficulty of the flexible cover plate 100 is reduced, which is conducive to the improvement of production yield.

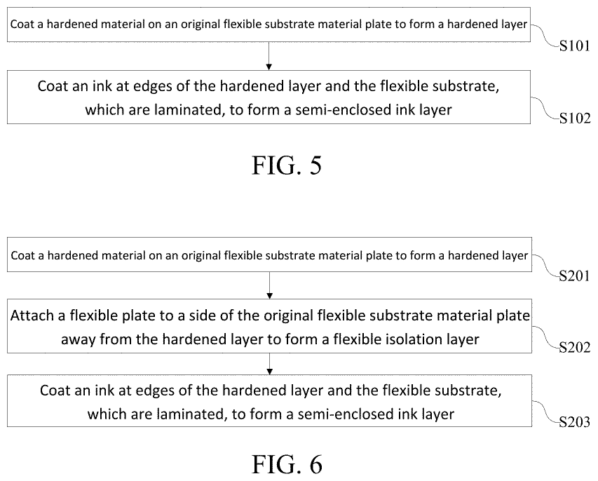

Referring to FIG. 4 and FIG. 5, FIG. 5 is a schematic flowchart of a manufacturing method of the flexible cover plate 100 according to an embodiment of the present application.

The present application further provides the manufacturing method of the flexible cover plate 100 comprises the steps as follows.

Step S101: a hardened material is coated on an original flexible substrate 10 material plate to form the hardened layer 20.

The material of the flexible substrate 10 may be polyethylene terephthalate or polyimide, so that the flexible substrate 10 has flexibility and light transmittance. The hardened layer 20 is used to improve the surface hardness of the flexible substrate 10.

Step S102: an ink is coated at edges of the hardened layer 20 and the flexible substrate 10, which are laminated, to form a semi-enclosed ink layer.

The ink protective layer 30 is disposed at edges around the hardened layer 20 and the flexible substrate 10, which are laminated, thereby preventing the hardened layer 20 from cracking from the edge after bending with the flexible substrate 10 several times

Particularly, the ink protective layer 30 comprises a first protective layer 31, a second protective layer 32, and a third protective layer 33. The first protective layer 31 is disposed on a side of the flexible substrate 10 away from the hardened layer 20. The third protective layer 33 is disposed on a side of the hardened layer 20 away from the flexible substrate 10. The second protective layer 32 is attached to lateral edges of the hardened layer 20 and the flexible substrate 10, which are laminated, and is respectively connected to the first protective layer 31 and the third protective layer 33.

A thickness of the ink protective layer 30 may ranges from 2 microns to 10 microns, such as 2 microns, 3 microns, 5 microns, 8 microns, or 10 microns.

It can be understood that the area of the original flexible substrate 10 material plate is large enough to be divided into a plurality of sub-units for manufacturing the flexible cover plate 100. After the step S101, the original flexible substrate 10 material plate is cut into a plurality of portions for used in the step S102. In the step S102, the edges of each sub-unit are respectively coated with the ink to form an ink layer.

Referring to FIG. 4 and FIG. 6, FIG. 6 is a schematic flowchart of a manufacturing method of the flexible cover plate 100 according to an embodiment of the present application.

The present application further provides the manufacturing method of the flexible cover plate 100 comprises the steps as follows.

Step S201: a hardened material is coated on an original flexible substrate 10 material plate to form the hardened layer 20.

The material of the flexible substrate 10 may be polyethylene terephthalate or polyimide, so that the flexible substrate 10 has flexibility and light transmittance. The hardened layer 20 is used to improve the surface hardness of the flexible substrate 10.

Step S202: a flexible plate is attached to a side of the original flexible substrate 10 material plate away from the hardened layer 20 to form a flexible isolation layer 40.

After the step S201, the flexible isolation layer 40 is disposed on a side of the flexible substrate 10 away from the hardened layer 20. A material of the flexible isolation layer 40 may be polyethylene terephthalate or polyimide, so that the flexible isolation layer 40 has flexibility and light transmittance.

Step S203: an ink is coated at edges of the hardened layer 20 and the flexible substrate 10, which are laminated, to form a semi-enclosed ink layer.

The ink protective layer 30 is disposed at edges around the hardened layer 20 and the flexible substrate 10, which are laminated, thereby preventing the hardened layer 20 from cracking from the edge after bending with the flexible substrate 10 several times

Particularly, the ink protective layer 30 comprises a first protective layer 31, a second protective layer 32, and a third protective layer 33. The first protective layer 31 is disposed on a side of the flexible substrate 10 away from the hardened layer 20. The third protective layer 33 is disposed on a side of the hardened layer 20 away from the flexible substrate 10. The second protective layer 32 is attached to lateral edges of the hardened layer 20 and the flexible substrate 10, which are laminated, and is respectively connected to the first protective layer 31 and the third protective layer 33.

A thickness of the ink protective layer 30 may ranges from 2 microns to 10 microns, such as 2 microns, 3 microns, 5 microns, 8 microns, or 10 microns.

The flexible isolation layer 40 is also connected to the first protective layer 31. The flexible isolation layer 40 and the first protective layer 31 are used for connecting to the organic light-emitting panel 200 of the flexible display device 1000. Thus, the introduction of the flexible isolation layer 40 can ensure the flatness of the side of the flexible cover plate 100 provided with the first protective layer 31.

A material of the flexible isolation layer 40 may be polyethylene terephthalate or polyimide, so that the flexible isolation layer 40 has flexibility and light transmittance.

Particularly, the first protective layer 31 comprises a first ink area and a second ink area disposed at intervals. The flexible isolation layer 40 is filled between the first ink area and the second ink area.

The thicknesses of the first ink area and the second ink area are the same, and a surface of the flexible isolation layer 40 away from the flexible substrate 10 is flush with a surface of the first protective layer 31 away from the flexible substrate 10.

In the manufacturing method of the flexible cover plate 100 of the present application, the flexible isolation layer 40 is provided on a side of the flexible substrate 10 away from the hardened layer 20, thereby eliminating the step difference caused by the first protective layer 31 on the flexible substrate 10. In this way, the optical adhesive layer 300 with a thinner and uniform thickness can be used to bond the flexible cover plate 100 and the organic light-emitting panel 200 during use, thereby reducing the thickness of the flexible display device 1000, and improving the bending resistance thereof. Moreover, the bonding difficulty of the flexible cover plate 100 is reduced, which is conducive to the improvement of production yield.

In the present application, the terms such as “first” and “second” are used herein for purposes of description and are not intended to indicate or imply relative importance or to imply the number of indicated technical features. Thus, the feature defined as “first” and “second” may explicitly or implicitly include at least one of the features. In the description of the present application, “a plurality of” means at least two, such as two, or three, unless specified otherwise. All directional indications (such as up, down, left, right, front, back, etc.) in the embodiments of the present application are only used to explain the relative positional relationship, movement situation, etc., between the components in a specific configuration (as shown in the drawing). If the specific configuration changes, the directional indications will change accordingly. Furthermore, the terms “comprising” and “having” and any variations thereof are intended to cover non-exclusive inclusion. For example, a process, a method, a system, a product, or a device including a series of steps or components is not limited to the listed steps or components, but optionally further includes steps or components not listed, or optionally further includes other steps or components inherent to these processes, methods, products, or devices.

The foregoing descriptions are merely embodiments of the present application, and are not intended to limit the scope of the present application. An equivalent structural or equivalent process alternation made by using the content of the specification and drawings of the present application, or an application of the content of the specification and drawings directly or indirectly to another related technical field, shall fall within the protection scope of the present application.

What is claimed is:

1. A flexible cover plate used as a protective cover of a flexible display device, comprising:
a flexible substrate;
a hardened layer disposed on a side of the flexible substrate; and
an ink protective layer disposed at edges around the hardened layer and the flexible substrate, which are laminated.

2. The flexible cover plate according to claim 1, wherein the ink protective layer comprises a first protective layer, a second protective layer, and a third protective layer, the first protective layer is disposed on a side of the hardened layer away from the flexible substrate, the second protective layer is disposed on a side of the flexible substrate away from the hardened layer, and the third protective layer is attached to lateral edges of the hardened layer and the flexible substrate, which are laminated, and is respectively connected to the first protective layer and the second protective layer.

3. The flexible cover plate according to claim 1, wherein a thickness of the ink protective layer ranges from 2 microns to 10 microns.

4. The flexible cover plate according to claim 2, wherein the flexible cover plate further comprises a flexible isolation layer, the flexible isolation layer is disposed on a side of the flexible substrate away from the hardened layer, and is connected to the first protective layer, and the flexible isolation layer and the first protective layer are used for connecting to an organic light-emitting panel of the flexible display device.

5. The flexible cover plate according to claim 4, wherein a surface of the flexible isolation layer away from the flexible substrate is flush with a surface of the first protective layer away from the flexible substrate.

6. The flexible cover plate according to claim 4, wherein a material of the flexible substrate is polyethylene terephthalate or polyimide, and a material of the flexible isolation layer is polyethylene terephthalate or polyimide.

7. A flexible display device, comprising an organic light-emitting panel and a flexible cover plate disposed in a stack, wherein the flexible cover plate comprises:
a flexible substrate;
a hardened layer disposed on a side of the flexible substrate; and
an ink protective layer disposed at edges around where the hardened layer and the flexible substrate, which are laminated.

8. The flexible display device according to claim 7, wherein the ink protective layer comprises a first protective layer, a second protective layer, and a third protective layer, the first protective layer is disposed on a side of the hardened layer away from the flexible substrate, the second protective layer is disposed on a side of the flexible substrate away from the hardened layer, and the third protective layer is attached to lateral edges of the hardened layer and the flexible substrate, which are laminated, and is respectively connected to the first protective layer and the second protective layer.

9. The flexible display device according to claim 7, wherein a thickness of the ink protective layer ranges from 2 microns to 10 microns.

10. The flexible display device according to claim 8, wherein the flexible cover plate further comprises a flexible isolation layer, the flexible isolation layer is disposed on a side of the flexible substrate away from the hardened layer, and is connected to the first protective layer, and the flexible isolation layer and the first protective layer are used for connecting to an organic light-emitting panel of the flexible display device.

11. The flexible display device according to claim 10, wherein a surface of the flexible isolation layer away from the flexible substrate is flush with a surface of the first protective layer away from the flexible substrate.

12. The flexible display device according to claim 10, wherein a material of the flexible substrate is polyethylene terephthalate or polyimide, and a material of the flexible isolation layer is polyethylene terephthalate or polyimide.

13. A manufacturing method of a flexible cover plate, comprising:
coating a hardened material on an original flexible substrate material plate to form a hardened layer; and
coating an ink at edges of the hardened layer and the flexible substrate, which are laminated, to form a semi-enclosed ink layer.

14. The manufacturing method according to claim 13, wherein after the step of coating the hardened material on the original flexible substrate material plate to form the hardened layer, the manufacturing method comprises cutting the original flexible substrate material plate into a plurality of portions.

15. The manufacturing method according to claim 13, wherein after the step of coating the hardened material on the original flexible substrate material plate to form the hardened layer, the manufacturing method comprises attaching a flexible plate to a side of the original flexible substrate material plate away from the hardened layer to form a flexible isolation layer.
